(19) United States
(12) Patent Application Publication
(10) Pub. No.: US 2013/0180588 A1
(43) Pub. Date: Jul. 18, 2013

(54) HIGH TO ULTRAHIGH MOLECULAR WEIGHT POLYETHYLENE BACKSHEETS FOR PHOTOVOLTAIC DEVICES AND METHODS RELATING THERETO

(71) Applicants: Julia Hufen, Rheinberg (DE); Jeffrey Haley, Norwood, OH (US); Christopher McGrady, Florence, KY (US); Kerstin Luedtke, Markkleeberg (DE); Anthony Verrocchi, Covington, KY (US); Janine Bauer, Duisburg (DE); Barry Daggs, Dallas, TX (US); Bernard Jason Smith, Cincinnati, OH (US)

(72) Inventors: Julia Hufen, Rheinberg (DE); Jeffrey Haley, Norwood, OH (US); Christopher McGrady, Florence, KY (US); Kerstin Luedtke, Markkleeberg (DE); Anthony Verrocchi, Covington, KY (US); Janine Bauer, Duisburg (DE); Barry Daggs, Dallas, TX (US); Bernard Jason Smith, Cincinnati, OH (US)

(73) Assignee: Ticona LLC, Florence, KY (US)

(21) Appl. No.: 13/737,399

(22) Filed: Jan. 9, 2013

Related U.S. Application Data
(60) Provisional application No. 61/586,359, filed on Jan. 13, 2012.

(51) Int. Cl. H01L 31/048; C08F 110/02

(52) U.S. Cl. CPC H01L 31/0487; C08F 110/02
USPC 136/259; 428/220; 264/162; 264/319; 526/352; 524/585

(57) ABSTRACT

Generally, solar cell backsheets may include high to ultrahigh molecular weight polyethylene. Advantageously, said backsheets may be single layer structures. Said backsheets may be used in conjunction with photovoltaic devices, photovoltaic modules, photovoltaic arrays, or components thereof. Said backsheets may be formed by methods including compression molding, compression molding then skiving, RAM extrusion, screw extrusion, band sintering, and hybrids thereof.

### CROSS-REFERENCE TO RELATED APPLICATIONS

This application claims the benefit of U.S. Provisional Application No. 61/586,359, filed Jan. 13, 2012.

### BACKGROUND

The present invention relates to high to ultrahigh molecular weight polyethylene backsheets for photovoltaic devices and methods relating thereto.

Solar power is one of the more desirable types of renewal energy as it is an abundant energy with over 120,000 terawatts available annually. For years it has been touted as one of the most promising hydrocarbon alternative energies for our increasingly industrialized society. Even though the amount of solar power theoretically available far exceeds most, if not all, other energy sources (renewable or not), there remains practical challenges to utilizing this energy. Generally, solar power remains subject to a number of limitations that have kept it from fulfilling the promise it holds.

In one regard, photovoltaic devices are typically produced as complex layered structures. One such layer, that is complex in and of itself, is the backsheet. The backsheet is generally the surface of the photovoltaic device that is opposite the solar source and has desired properties that assist in the operation, preferably long-term operation, of photovoltaic devices. Desirable properties for a solar cell backsheet may include, but are not limited to, high electrical insulation, high structural stability and/or integrity, thermal stability at operating temperatures, outdoor weatherability, low moisture permeability, electrical insulation, or any combination thereof.

In order to provide the requisite properties current backsheets are typically designed with several layers, e.g., a trilaminate of polyvinyl fluoride-polyethylene terephthalate-polyvinyl fluoride. Production of a multilayer structure that provides a desired combination of properties may be time consuming and increase the manufacturing costs of photovoltaic devices. Multilayer structures may also require additional steps and/or surface treatment to ensure adhesion of these layers. Further, when the temperature of the backsheet increases during operation, multilayer laminates have the potential to delaminate, which can adversely effect the operation of the photovoltaic device.

It may be of value to one skilled in the art to have a single layer backsheet that provides for less complex and costly design and manufacturing, while still providing a desired combination of properties that assist in the operation of photovoltaic devices.

### SUMMARY OF THE INVENTION

The present invention relates to high to ultrahigh molecular weight polyethylene backsheets for photovoltaic devices and methods relating thereto.

Some embodiments of the present invention may provide a solar cell backsheet that includes high to ultrahigh molecular weight polyethylene. In some embodiments, said solar cell backsheet may be a single layer structure.

Some embodiments of the present invention may provide a method that includes compression molding a matrix material into a billet and skiving the billet to yield a sheet having a thickness of about 3 mm or less. The matrix material may include high to ultrahigh molecular weight polyethylene.

Some embodiments of the present invention may provide a method that includes compression molding a matrix material into a sheet having a thickness of about 3 mm or less. The matrix material may include high to ultrahigh molecular weight polyethylene.

Some embodiments of the present invention may provide a method that includes forming a layered article comprising the sheet and at least one layer. The sheet may include high to ultrahigh molecular weight polyethylene.

Some embodiments of the present invention may provide a photovoltaic device that includes a photovoltaic layer and a backsheet. The backsheet may include high to ultrahigh molecular weight polyethylene. The photovoltaic device may further include a cover layer, a first encapsulant layer, and a second encapsulant layer such that in order the photovoltaic device comprises the cover layer, the first encapsulant film, the photovoltaic layer, the second encapsulant film, and the backsheet.

Some embodiments of the present invention may provide a photovoltaic module that includes a plurality of photovoltaic devices with at least one photovoltaic device that includes a photovoltaic layer and a backsheet. The backsheet may include high to ultrahigh molecular weight polyethylene.

Some embodiments of the present invention may provide a kit that includes a set of instructions and at least one photovoltaic device or component thereof that includes a photovoltaic layer and a backsheet. The backsheet may include high to ultrahigh molecular weight polyethylene.

Some embodiments of the present invention may provide a method that includes attaching a photovoltaic device or component thereof to a receiver. The photovoltaic device or component thereof may include a device frame, a photovoltaic layer, and a backsheet that includes high to ultrahigh molecular weight polyethylene. The receiver may be capable of receiving at least a portion of the device frame so as to hold the photovoltaic device or component thereof in a set position relative to the receiver.

Some embodiments of the present invention may provide a method that includes attaching the photovoltaic device or component thereof to a surface, a device frame, and/or a module frame. The photovoltaic device or component thereof may include a photovoltaic layer and a backsheet. The backsheet may include high to ultrahigh molecular weight polyethylene.

Some embodiments of the present invention may provide a kit that includes a set of instructions and at least one photovoltaic module or component thereof that includes at least one photovoltaic device. The photovoltaic device may include a photovoltaic layer and a backsheet. The backsheet may include high to ultrahigh molecular weight polyethylene.

Some embodiments of the present invention may provide a method that includes integrating a photovoltaic module or component thereof into a photovoltaic array. The photovoltaic module or component thereof may include at least one photovoltaic device that includes a photovoltaic layer and a backsheet. The backsheet may include high to ultrahigh molecular weight polyethylene.

The features and advantages of the present invention will be readily apparent to those skilled in the art upon a reading of the description of the preferred embodiments that follows.

### BRIEF DESCRIPTION OF THE DRAWINGS

The following figures are included to illustrate certain aspects of the present invention, and should not be viewed as exclusive embodiments. The subject matter disclosed is capable of considerable modifications, alterations, combinations, and equivalents in form and function, as will occur to those skilled in the art and having the benefit of this disclosure.

FIG. 1 provides an illustration of a bimodal molecular weight distribution.

FIGS. 2A-C provide illustrations of nonlimiting examples of layered articles comprising backsheets of the present invention.

FIGS. 3A-F provide nonlimiting examples of layered photovoltaic device configurations comprising backsheets of the present invention.

FIGS. 4A-B provide Young's modulus data for heat treated samples comprising high to ultrahigh molecular weight polyethylene.

FIGS. 5A-B provide stress at 50% strain data for heat treated samples comprising high to ultrahigh molecular weight polyethylene.

FIGS. 6A-B provide stress at break data for heat treated samples comprising high to ultrahigh molecular weight polyethylene.

FIGS. 7A-B provide elongation to break data for heat treated samples comprising high to ultrahigh molecular weight polyethylene.

### DETAILED DESCRIPTION

The present invention relates to high to ultrahigh molecular weight polyethylene backsheets for photovoltaic devices and methods relating thereto.

The present invention provides, in some embodiments, backsheets of high to ultrahigh molecular weight polyethylene in a single layer that have a desired combination of properties, e.g., high electrical insulation, high structural stability and/or integrity, thermal stability at operating temperatures, outdoor weatherability, low moisture permeability, electrical insulation, or any combination thereof. Single layer backsheets with such properties may advantageously simplify the production of backsheets for photovoltaic devices. Further, as high to ultrahigh molecular weight polyethylene is less expensive relative to fluorinated polymers of traditional backsheets, the cost of backsheet production and consequently photovoltaic device production may be reduced, thereby reducing a barrier to implementation by providing cost advantages enabling expanded use of this clean technology.

Further, single layer backsheets may be advantageous to multilayer backsheets in that interlayer delamination risk can be avoided, which may reduce the frequency and cost of repair due to backsheet malfunction or failure.

It should be noted that when “about” is provided at the beginning of a numerical list, “about” modifies each number of the numerical list. It should be noted that in some numerical listings of ranges, some lower limits listed may be greater than some upper limits listed. One skilled in the art will recognize that the selected subset will require the selection of an upper limit in excess of the selected lower limit.

In some embodiments, backsheets of the present invention may comprise high to ultrahigh molecular weight polyethylene. As used herein, the use of “high to ultrahigh molecular weight polyethylene” should be taken to encompass high molecular weight polyethylene, very-high molecular weight polyethylene, ultrahigh molecular weight polyethylene, and any blend thereof. As used herein, the term “high molecular weight polyethylene” refers to polyethylene having an average molecular weight of about 300,000 g/mol to about 1,000,000 g/mol. As used herein, the term “very-high molecular weight polyethylene” refers to polyethylene having an average molecular weight of about 1,000,000 g/mol to about 3,000,000 g/mol. As used herein, the term “ultrahigh molecular weight polyethylene” refers to polyethylene having an average molecular weight of about 3,000,000 g/mol to about 20,000,000 g/mol.

In some embodiments, backsheets of the present invention may comprise high to ultrahigh molecular weight polyethylene having an average molecular weight ranging from a lower limit of about 300,000 g/mol, 500,000 g/mol, 1,000,000 g/mol, 2,000,000 g/mol, 3,000,000 g/mol, or 5,000,000 g/mol to an upper limit of about 20,000,000 g/mol, 15,000,000 g/mol, 12,000,000 g/mol, 10,000,000 g/mol, 9,000,000 g/mol, 5,000,000 g/mol, 3,000,000 g/mol, or 1,000,000 g/mol, and wherein the average molecular weight may range from any lower limit to any upper limit and encompass any range therebetween. In some embodiments, the high to ultrahigh molecular weight polyethylene may be a homopolymer, copolymer, or blend thereof.

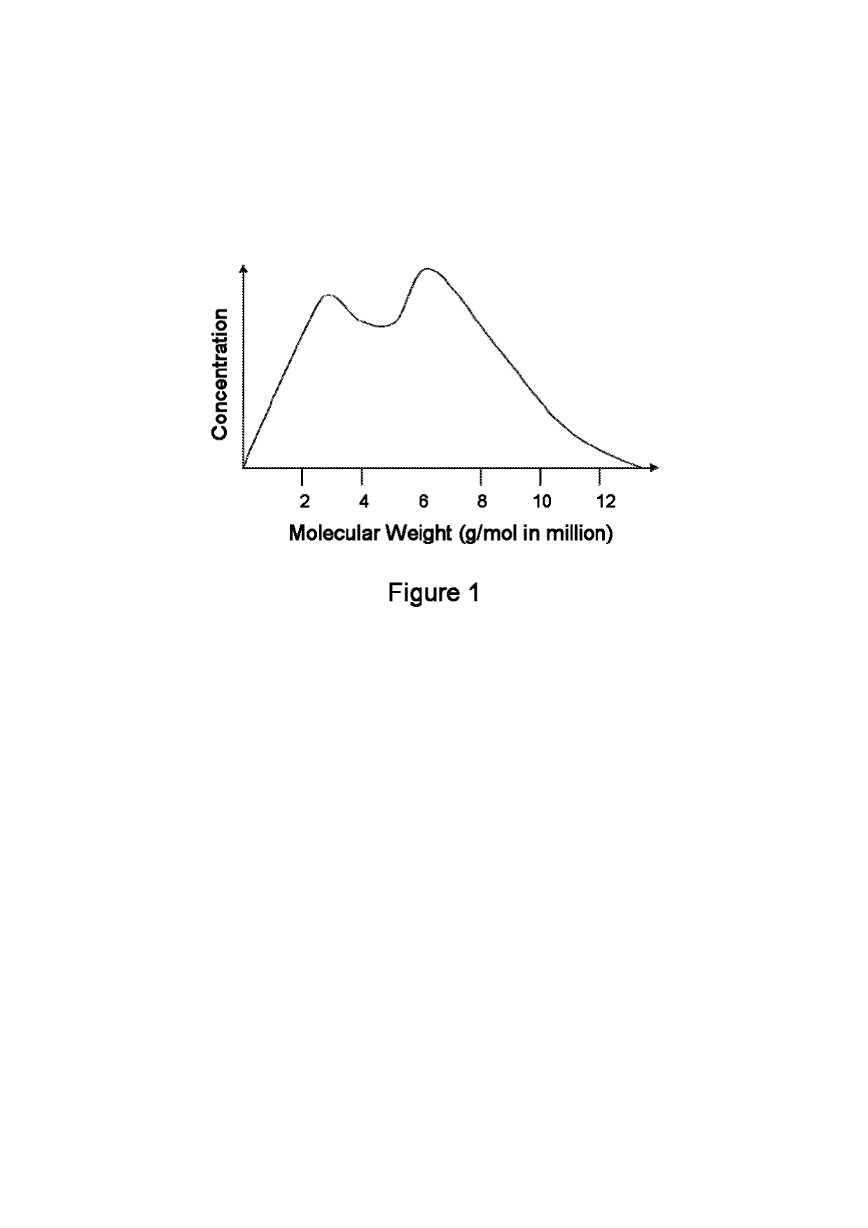

In some embodiments, backsheets of the present invention may comprise high to ultrahigh molecular weight polyethylene having a multimodal (e.g., bimodal or trimodal) molecular weight distribution. As used herein, a multimodal molecular weight distribution should be taken to mean having at least two local maxima in the plot of molecular weight distribution. FIG. 1 provides an illustration of a bimodal molecular weight distribution. One skilled in the art should understand the plurality of methods by which a multimodal molecular weight distribution may be achieved including, but not limited to, direct polymerization (e.g., cascade and/or multi-step polymerization), choice of catalyst (single or multi-side catalysts), blending of material, or any combination thereof.

In some embodiments, backsheets of the present invention may comprise high to ultrahigh molecular weight polyethylene having a multimodal molecular weight distribution with at least one mode having a peak molecular weight ranging from a lower limit of about 300,000 g/mol, 500,000 g/mol, 1,000,000 g/mol, 2,000,000 g/mol, 3,000,000 g/mol, or 5,000,000 g/mol to an upper limit of about 20,000,000 g/mol, 15,000,000 g/mol, 12,000,000 g/mol, 10,000,000 g/mol, 9,000,000 g/mol, 5,000,000 g/mol, 3,000,000 g/mol, or 1,000,000 g/mol, and wherein the peak molecular weight may range from any lower limit to any upper limit and encompass any range therebetween.

In some embodiments, backsheets of the present invention comprising high to ultrahigh molecular weight polyethylene may have a combination of desirable properties for backsheets. Suitable properties for backsheets may include, but not are not limited to, high electrical insulation, high structural stability and/or integrity, thermal stability at operating temperatures, outdoor weatherability, low moisture permeability, electrical insulation, or any combination thereof.

In some embodiments, backsheets of the present invention may have a moisture permeability characterized by a water vapor transmission of about 20 g/m²*day or less. In some embodiments, backsheets of the present invention may have a moisture permeability characterized by a water vapor transmission ranging from a lower limit of about 2 g/m²*day to an upper limit of about 20 g/m²*day.

In some embodiments, backsheets of the present invention may have a relative thermal index (RTI) of about 90° C. to about 150° C. as determined by the standard method of UL746C.

In some embodiments, backsheets of the present invention may have a peel strength to an ethylene vinyl acetate copolymer encapsulant film of about 60 N/cm or greater as measured by the standard method ASTM D1876.

In some embodiments, backsheets of the present invention may have a partial discharge value of about 1000 V or greater as measured by the standard method IEC 60664-1.

In some embodiments, backsheets of the present invention may have dielectric strength of about 2500 V/mil or greater.

In some embodiments, backsheets of the present invention may consist essentially of a monolayer structure comprising high to ultrahigh molecular weight polyethylene.

In some embodiments, backsheets of the present invention may include multiple layers. In some embodiments, backsheets of the present invention may comprise at least one layer that comprises high to ultrahigh molecular weight polyethylene laminated to another layer comprising traditional backsheet materials (e.g., polyesters, polyvinyl fluorides, polyethylene terephthalate, polyamide, ethylene vinyl acetate copolymers, aluminum, polyolefins, and the like, or any combination thereof).

In some embodiments, the backsheets of the present invention may have a thickness of about 3 mm or less. In some embodiments, the backsheets of the present invention may have a thickness ranging from a lower limit of about 10 microns, 50 microns, 100 microns, 250 microns, 500 microns, or 1 mm to an upper limit of about 3 mm, 2 mm, 1 mm, 500 microns, or 250 microns, and wherein the thickness may range from any lower limit to any upper limit and encompass any subset therebetween.

In some embodiments, backsheets of the present invention may comprise high to ultrahigh molecular weight polyethylene and additives. Suitable additives for use in conjunction with the present invention may include, but not be limited to, heat stabilizers, antioxidants, light stabilizing additives, UV absorbers, light diffusing agents, halogenated flame retardants, non-halogenated flame retardants, reinforcing additives, crosslinking agents, lubricants, optical brighteners, colorants, metal deactivating agents, or any combination thereof. One skilled in the art with the benefit of this disclosure should understand the appropriate concentrations of each additive individually and relative to each other so as to achieve a desired result.

Suitable heat stabilizers for use in conjunction with the present invention may include, but are not limited to, phosphites, aminic antioxidants, phenolic antioxidants, or any combination thereof.

Suitable antioxidants for use in conjunction with the present invention may include, but are not limited to, secondary aromatic amines, benzofuranones, hindered phenols, or any combination thereof.

Suitable light stabilizing additives for use in conjunction with the present invention may include, but are not limited to, 2-(2′-hydroxyphenyl)-benzotriazoles, 2-hydroxy-4-alkoxybenzophenones, nickel containing light stabilizers, 3,5-di-tert-butyl-4-hydroxbenzoates, sterically hindered amines (HALS), or any combination thereof.

Suitable UV absorbers for use in conjunction with the present invention may include, but are not limited to, substituted 2-hydroxybenzophenones, substituted 2-hydroxybenzotriazoles, hydroxyphenylbenzotriazole class (Tinuvins), or any combination thereof.

Suitable halogenated flame retardants for use in conjunction with the present invention may include, but are not limited to, tetrabromobisphenol A (TBBA), tetrabromophthalic acid anhydride, dedecachloropentacyclooctadecadiene (dechlorane), hexabromocyclodedecane, chlorinated paraffins, or any combination thereof.

Suitable non-halogenated flame retardants for use in conjunction with the present invention may include, but are not limited to, resorcinol diphosphoric acid tetraphenyl ester (RDP), ammonium polyphosphate (APP), phosphine acid derivatives, triaryl phosphates, trichloropropylphosphate (TCPP), magnesium hydroxide, aluminum trihydroxide, antimony trioxide, powdered siloxane (e.g., Dow Corning® 4-7081 Resin Modifier and Dow Corning® 4-7105 Resin Modifier available from Dow Corning®), or any combination thereof.

Suitable reinforcing additives for use in conjunction with the present invention may include, but are not limited to, wood flour, glass spheres, glass fibers, graphite, aluminum powder, talc, chalk, silicates, carbonates, or any combination thereof.

Suitable crosslinking agents for use in conjunction with the present invention may include, but are not limited to, peroxides, dicumylperoxide, 1-di(tert-butylperoxy)-3,3,5-trimethylcyclohexane, a,a′-bis(tert-butylperoxy)-diisoproplybenzenesilane, coupling agents, or any combination thereof. In some embodiments, crosslinking by external methods may be performed during and/or after forming the backsheet (or precursor thereof, described further herein). Suitable external methods may include, but are not limited to, radiation exposure, e.g., beta or gamma irradiation.

Suitable lubricants for use in conjunction with the present invention may include, but are not limited to, silicone oil, waxes, greases, molybdenum disulfide, or any combination thereof.

Suitable colorants for use in conjunction with the present invention may include, but are not limited to, inorganic and organic based color pigments.

Generally, backsheets of the present invention may comprise high to ultrahigh molecular weight polyethylene, which in some embodiments may be in a single layer structure or a multi-layer structure. In some embodiments, backsheets of the present invention may be further characterized by one or more of the following features in any combination: the molecular weight distribution of the high to ultrahigh molecular weight polyethylene according to any embodiment disclosed herein, the thickness of the backsheet according to any embodiment disclosed herein, the desired properties of the backsheet according to any embodiment disclosed herein (e.g., relative thermal index, peel strength to an ethylene vinyl acetate copolymer encapsulant film, partial discharge value, dielectric strength, or any combination thereof), and/or the additives of the backsheets according to any embodiment disclosed herein.

Some embodiments may involve forming sheets or backsheets of the present invention according to any backsheet embodiments described herein. Suitable methods of forming may include, but are not limited to, compression molding, band sintering, compression molding of a billet (or the like) then skiving, RAM extrusion of a billet (or the like) then skiving, screw extrusion of a billet (or the like) then skiving, and the like, or any hybrid thereof. As used herein, the term “sheet” refers generally to the as produced material without additional processing and encompasses sheet-like structures including tapes. In some embodiments, a sheet may be a backsheet of the present invention. In some embodiments, a sheet may be further processed (e.g., applying an adhesive or treating to form a hydrophilic surface) to yield a backsheet of the present invention.

Compression molding may generally include applying pressure to a matrix material (e.g., high to ultrahigh molecular weight polyethylene and any optional additives) to form a desired shape, e.g., a sheet, a billet, and the like. In some embodiments, compression molding may further include increasing the temperature while applying pressure. One skilled in the art should understand the necessary apparatuses, machinery, and procedural requirements for compression molding.

Skiving may generally include shaving or scarfing compression molded billets, or the like, to yield sheets. One skilled in the art should understand the necessary apparatuses, machinery, and procedural requirements for skiving.

Band sintering may generally include continuously (or substantially continuously) passing matrix material through a process that applies heat and pressure to produce a sheet, a tape, or the like. One skilled in the art should understand the necessary apparatuses, machinery, and procedural requirements for band sintering, e.g., using hot rollers to achieve simultaneous heating and compression.

Extrusion may generally include continuously (or substantially continuously) extruding a polymer melt comprising matrix material through a die to produce a desired shape, e.g., a sheet, a billet, and the like. Suitable extrusion methods may include, but are not limited to, RAM extrusion and screw extrusion. One skilled in the art should understand the necessary apparatuses, machinery, and procedural requirements for extrusion.

Some embodiments of the present invention may involve first forming a billet (or the like) then skiving sheets from the billet. In some embodiments, forming a billet may involve extrusion, compression molding, and the like.

In some embodiments, the sheets may have a thickness of about 3 mm or less. In some embodiments, the resultant sheets may have a thickness ranging from a lower limit of about 10 microns, 50 microns, 100 microns, 250 microns, 500 microns, or 1 mm to an upper limit of about 3 mm, 2 mm, 1 mm, 500 microns, or 250 microns, and wherein the thickness may range from any lower limit to any upper limit and encompass any subset therebetween.

Some embodiments of the present invention may involve treating at least a portion of the surface of the sheets or backsheets to produce a hydrophilic surface. Suitable methods of producing a hydrophilic surface may include, but are not limited to, exposing the surface to a plasma, exposing the surface to a corona, exposing the surface to a strong oxidizer, chemically treating the surface with gas and/or liquid phase chemical, or any combination thereof.

Some embodiments of the present invention may involve applying an adhesive and/or primer to at least a portion of the sheets or backsheets. Adhesives and/or primers may be applied as thin coatings, patterned coatings, webs, nets, lattices, grids, discontinuous layers (e.g., lightly sprayed on), and the like to the backsheets of the present invention by any suitable method known to one skilled in the art. Suitable adhesives for use in conjunction with the present invention may include, but are not limited to, glue, gelatin, caesin, starch, cellulose esters, aliphatic polyesters, poly(alkanoates), aliphatic-aromatic polyesters, sulfonated aliphatic-aromatic polyesters, polyamide esters, rosin/polycaprolactone triblock copolymers, rosin/poly(ethylene adipate) triblock copolymers, rosin/poly(ethylene succinate) triblock copolymers, poly(vinyl acetates), poly(ethylene-co-ethylacrylate), poly(ethylene-co-methyl acrylate), poly(ethylene-co-propylene), poly(ethylene-co-1-butene), poly(ethylene-co-1-pentene), poly(styrene), acrylics, polyurethanes, sulfonated polyester urethane dispersions, nonsulfonated urethane dispersions, urethane-styrene polymer dispersions, non-ionic polyester urethane dispersions, acrylic dispersions, silanated anionic acrylate-styrene polymer dispersions, anionic acrylate-styrene dispersions, anionic acrylate-styrene-acrylonitrile dispersions, acrylate-acrylonitrile dispersions, vinylchloride-ethylene emulsions, vinylpyrrolidone/styrene copolymer emulsions, carboxylated and noncarboxylated vinyl acetate ethylene dispersions, vinyl acetate homopolymer dispersions, polyvinyl chloride emulsions, polyvinylidene fluoride dispersions, ethylene acrylic acid dispersions, polyamide dispersions, anionic carboxylated or noncarboxylated acrylonitrile-butadiene-styrene emulsions and acrylonitrile emulsions, resin dispersions derived from styrene, resin dispersions derived from aliphatic and/or aromatic hydrocarbons, styrene-maleic anhydrides, and the like, or any combination thereof. Suitable primers for use in conjunction with the present invention may include, but are not limited to, gamma-chloropropylmethoxysilane, vinyltrichlorosilane, vinyltriethoxysilane, vinyltris(beta-methoxyethoxy)silane, gamma-methacryloxypropyltrimethoxysilane, beta-(3,4-epoxycyclohexyl)ethyltrimethoxysilane, gammaglycidoxypropyltrimethoxysilane, vinyl-triacetoxysilane, gamma-mercaptopropyltrimethoxysilane, gamma-aminopropyltriethoxysilane, N-beta-(aminoethyl)-gamma-aminopropyl-trimethoxysilane, and the like, or any combination thereof.

Some embodiments of the present invention may involve a combination of (in any order) treating at least a portion of the surface of the sheets to produce a hydrophilic surface and applying an adhesive and/or primer to at least a portion of the sheets.

In some embodiments, backsheets of the present invention may have at least a portion of the surface being hydrophilic. In some embodiments, backsheets of the present invention may have an adhesive and/or primer on at least a portion of the surface of the backsheets. In some embodiments, backsheets of the present invention may have at least a portion of the surface being hydrophilic and a portion of the surface having an adhesive and/or primer disposed thereon. In some embodiments, the portion of the surface that is hydrophilic and the portion of the surface with an adhesive and/or primer thereon may be the same, different, or overlapping. In some embodiments, the portion of the surface that is hydrophilic and the portion of the surface with an adhesive and/or primer thereon may be on the same or opposing sides of the backsheets.

In some embodiments, hydrophilic surfaces and surfaces with adhesives and/or primers disposed thereon may assist in forming layered articles with backsheets of the present invention.

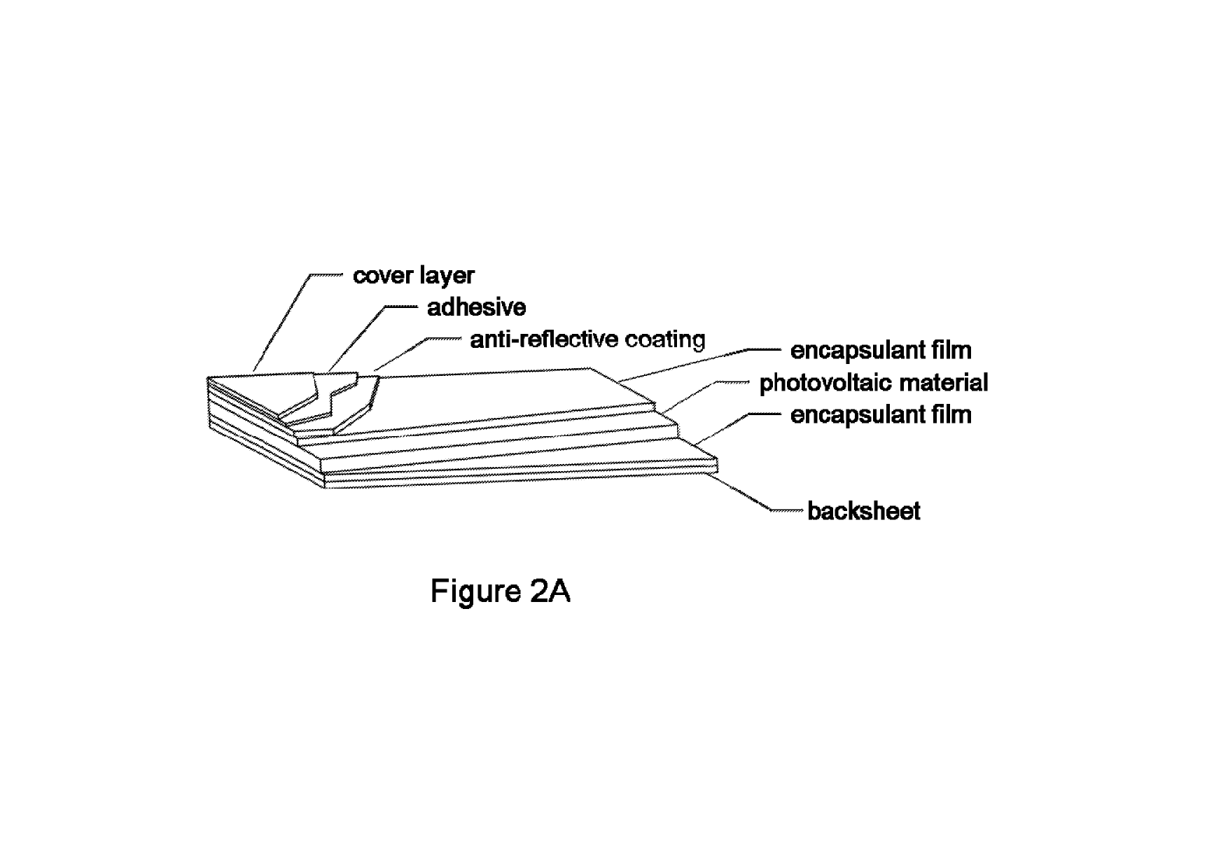

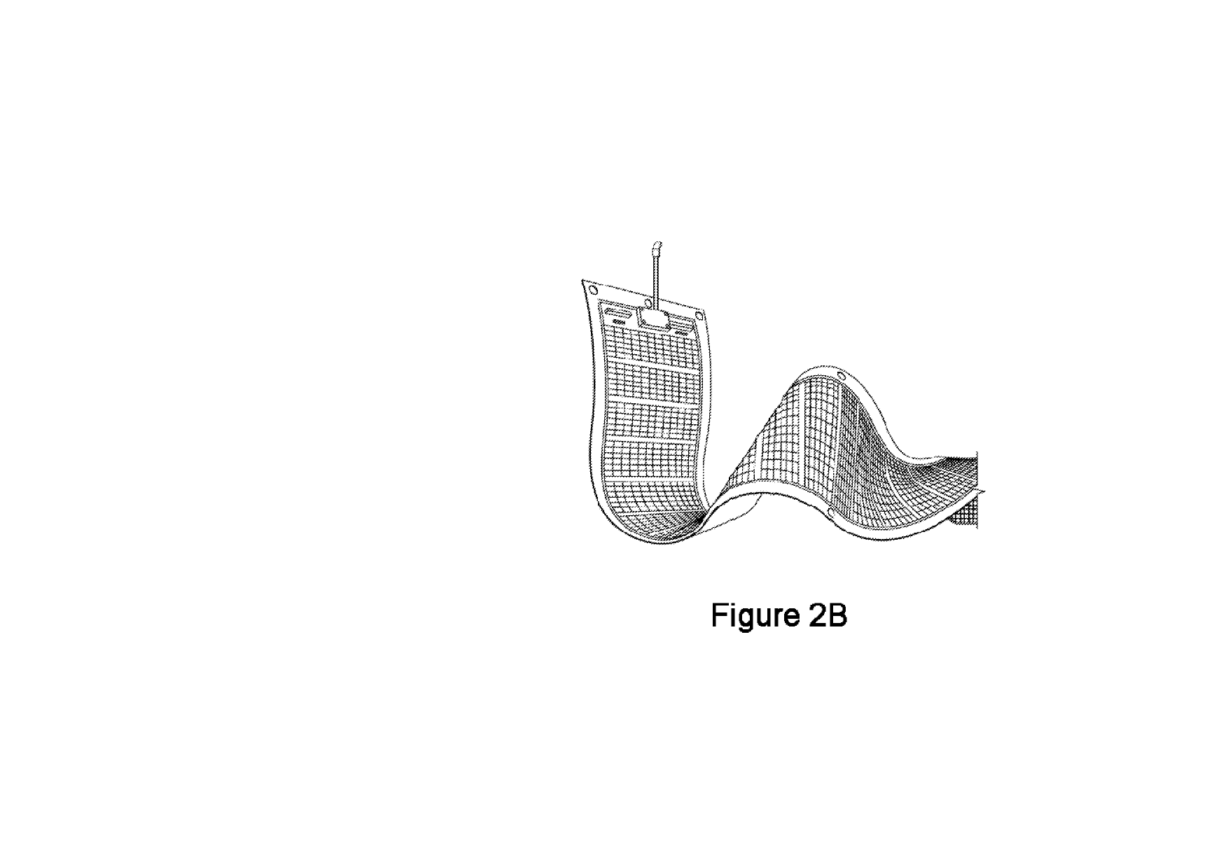

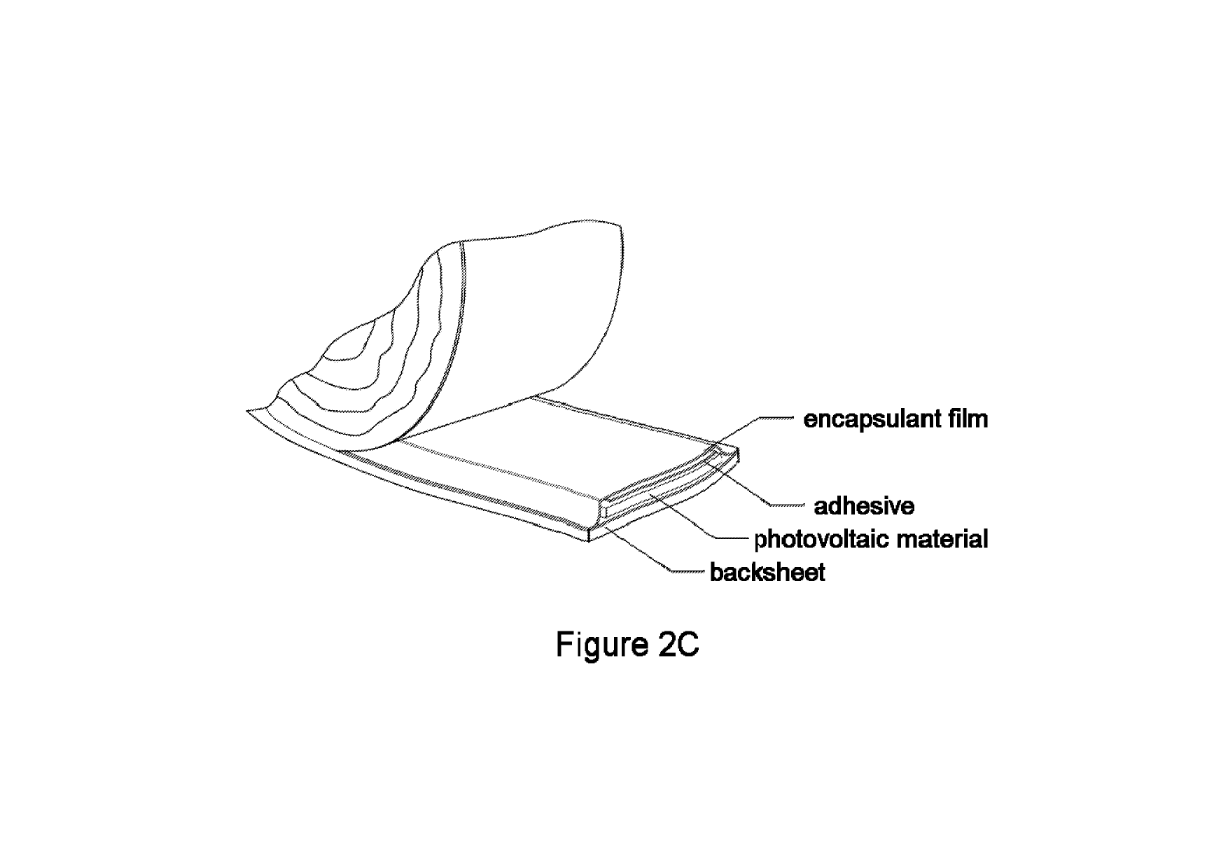

Some embodiments may involve forming a layered article with at least one layer comprising a backsheet of the present invention. Nonlimiting examples of layered articles, some of which are illustrated in FIGS. 2A-C, may include, but are not limited to, solar modules (a nonlimiting example of which is illustrated in FIG. 2A), components of solar cells or modules, solar sheets or films (nonlimiting examples of which are illustrated in FIGS. 2B-C), encapsulant film/backsheet articles, and the like. Additional layers, films, and/or coatings in the layered article may include, but are not limited to, substantially transparent solids (e.g., glass, quartz, or thermoplastic polymers like PLEXIGLAS®), encapsulant films, adhesives, anti-reflective films, electrodes, photovoltaic materials, polymeric films, substantially transparent resin films, and the like, or any combination thereof. It should be noted that the terms “layers,” “films,” “coatings,” and the like do not necessarily indicate an absolute thickness or relative thickness and includes layers that may have holes, e.g., webs, nets, lattices, grids, discontinuous layers (e.g., lightly sprayed on adhesives), and the like.

As used herein, the term “photovoltaic device” refers generally to devices for converting electromagnetic radiation to electricity using the photovoltaic effect, e.g., solar cells, solar films, solar sheets, and the like. As used herein, the term “photovoltaic module” refers generally to a module having at least two photovoltaic devices. As used herein, the term “photovoltaic array” refers generally to an array having at least two photovoltaic modules.

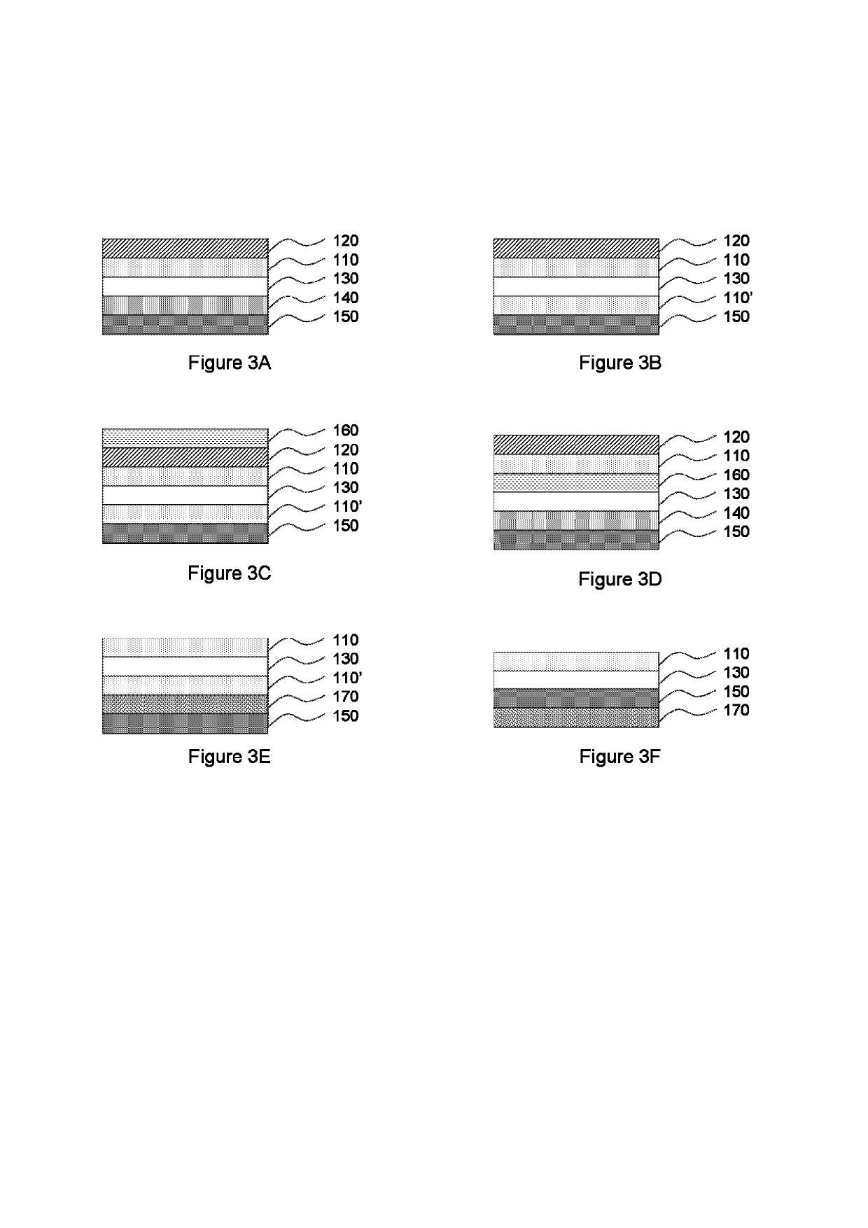

Photovoltaic devices or components thereof that comprise backsheets of the present invention may have a variety of layers in a variety of orders and may comprise at least one photovoltaic layer that comprises at least one photovoltaic material. One skilled in the art should understand the plurality of configurations in which a plurality of layers may be arranged to achieve operable photovoltaic devices or components thereof. Nonlimiting examples of at least some embodiments of said layered structures of photovoltaic devices or components thereof are illustrated in FIGS. 3A-F, where FIG. 3A includes in order layers of cover layer 120, encapsulant film 110, photovoltaic layer 130, other encapsulant film 140, and backsheet of the present invention 150; FIG. 3B includes in order layers of cover layer 120, encapsulant film 110, photovoltaic layer 130, encapsulant film 110′ (which may be the same or different than encapsulant film 110), and backsheet of the present invention 150; FIG. 3C includes in order anti-reflective layer 160, cover layer 120, encapsulant film 110, photovoltaic layer 130, encapsulant film 110′ (which may be the same or different than encapsulant film 110), and backsheet of the present invention 150; FIG. 3D includes in order cover layer 120, encapsulant film 110, anti-reflective layer 160, photovoltaic layer 130, encapsulant film 110′ (which may be the same or different than encapsulant film 110), and backsheet of the present invention 150; FIG. 3E includes in order encapsulant film 110, photovoltaic layer 130, encapsulant film 110′ (which may be the same or different than encapsulant film 110), adhesive layer 170, and backsheet of the present invention 150; and FIG. 3F includes in order encapsulant film 110, photovoltaic layer 130, backsheet of the present invention 150, and adhesive layer 170. It should be noted that the depiction of each layer in FIGS. 3A-F being the same thickness is not intended to be limiting or necessarily indicative of preferred embodiments, rather FIGS. 3A-F provide general illustrations of the order of some embodiments of layered articles that include backsheets of the present invention for use in photovoltaic devices or components thereof.

Suitable cover layers for use in conjunction with the present invention may be any material with transparency over at least a portion of the desired wavelength range (e.g., about 100 nm to about 1000 nm) and have the desired structural stability for a given layered article. Examples of cover layers may include, but are not limited to, glass, specialty glass with low-wavelength transparency, quartz, plexiglass, and the like, or any combination thereof.

Suitable encapsulant films for use in conjunction with the present invention may be any encapsulant film, which may include, but are not limited to, ethylene vinyl acetate copolymer films, polydimethylsiloxane films, polyvinylbutyral films, polyolefin plastomer films, polyolefin elastomer films, olefinic block copolymer films, polyurethane films, and the like, or any combination thereof. Suitable encapsulant films for use in conjunction with the present invention may be any encapsulant film, which may include, but are not limited to, poly(methyl methacrylate) with plasticized poly(vinyl chloride), poly(methyl methacrylate) with a vinyl acetate-vinyl chloride copolymer, poly(methyl methacrylate) with poly(vinylidene fluoride), and the like or any combination thereof. In some embodiments, the encapsulant films may include blends of any polymer matrix system described above. Further, suitable other encapsulant films may, in some embodiments, comprise additives, e.g., spectra broadening additives (e.g., organic luminophores and nanoparticles having at least one dimension of about 500 nm or less and an absorbance local maxima between about 100 nm and about 500 nm), quantum yield enhancers, plasticizers, thermal stabilizers, antioxidants, light stabilizers, pigments, dyes, anti-blocking agents, dispersants, surfactants, chelating agents, coupling agents, adhesives, primers, reinforcement additives, weathering stabilizers, light diffusing agents, anti-tarnish agents, peroxides, crosslinkers, curing agents, or any combination thereof.

Suitable photovoltaic materials for use in conjunction with the present invention may include, but are not limited to, semiconductor photovoltaic materials, organic photovoltaic materials (single layer or multilayer), and the like, or any hybrid thereof. Said photovoltaic materials may be in flexible forms or structurally firm materials. Nonlimiting examples of semiconductor photovoltaic materials may include crystalline, polycrystalline, or amorphous forms or quantum dot assemblies of silicon, germanium, magnesium sulfide, zinc sulfide, cadmium sulfide, copper indium gallium sulfide, magnesium selenide, zinc selenide, cadmium selenide, copper indium gallium selenide, copper indium gallium diselenide, aluminum phosphide, gallium phosphide, indium phosphide, aluminum arsenide, gallium arsenide, indium arsenide, gallium antimonide, aluminum antimonide, indium antimonide, zinc telluride, cadmium telluride, or any combination thereof. Nonlimiting examples of organic photovoltaic materials may include highly conjugated molecules, highly conjugated polymers, phthalocyaninne derivatives, perylene derivatives, poly[2-methoxy-5-(2′-ethyl-hexyloxy)-p-phenylene vinylene], fullerenes (e.g., C₆₀ and higher including endofullerenes), elongated fullerenes (e.g., C₇₀ and higher including endofullerenes), carbon nanotubes (e.g., single-walled, double-walled, or multiwalled including endonanotubes like peapods), and the like, or any combination thereof. One skilled in the art should understand the necessary elements to include in a photovoltaic layer of solar cells, other photovoltaic devices, or components thereof to achieve the necessary operability. By way of nonlimiting example, photovoltaic layers may include photovoltaic materials layered with electrodes. By way of another nonlimiting example, photovoltaic layers may include layered and/or heterogeneous photovoltaic materials (e.g., organic electron donors and organic electron acceptors as the photovoltaic materials) layered with electrodes.

Suitable anti-reflective layers for use in conjunction with the present invention may include, but are not limited to, index-matching layers, interference layers (single or multi-layered), and the like, or any combination thereof. One skilled in the art should understand that any anti-reflective layers in solar cells, other photovoltaic devices, or components thereof should have minimal impact the incident light to the photovoltaic layer.

Suitable adhesives for use in conjunction with the present invention may include, but are not limited to, those adhesives and primers listed above that may be applied to produce backsheets of the present invention. Further, in some embodiments, backsheets of the present invention may have a first adhesive and/or primer and during forming layered articles a second adhesive and/or primer may be applied. Further, in some embodiments, backsheets of the present invention may have no adhesive and/or primer and during forming layered articles an adhesive and/or primer may be applied. In some embodiments, adhesives may be disposed on the outer surface of the backsheet of the present invention relative to the layered article, as depicted in the nonlimiting examples in FIG. 3F, which may assist in attachment of the layered article to other surfaces (e.g., windows).

In some embodiments, forming layered articles (e.g., photovoltaic devices or components thereof) may involve laminating and/or adhering a backsheet of the present invention to at least one other layer described herein. In some embodiments, forming layered articles may involve vacuum laminating a backsheet of the present invention to at least one other layer described herein. In some embodiments, forming layered articles may involve compressing a backsheet of the present invention with at least one other layer described herein. In some embodiments, forming layered articles may involve spraying, patterning, and/or coating at least one other layer described herein onto a backsheet of the present invention. In some embodiments, forming layered articles may involve plasma treating and/or corona treating a backsheet of the present invention and/or at least one other layer described herein. In some embodiments, forming layered articles may involve extruding a thermoplastic polymer onto the sheet so as to form a film on at least a portion of a backsheet of the present invention. In some embodiments, such extrusion may at about 180° C. or less so as to minimize any adverse effects to the backsheet.

In some embodiments photovoltaic devices or components thereof may comprise a device frame for holding the layers of the photovoltaic devices or components thereof in a set relational configuration, where at least one photovoltaic device or component thereof includes at least one backsheet of the present invention and at least one photovoltaic layer. Some embodiments may involve installing, replacing, and/or removing photovoltaic devices or components thereof relative to a device frame. Some embodiments may involve attachment of photovoltaic devices or components thereof to a surface and/or cell frame. In some embodiments, said surfaces may include, but are not limited to, windows, transparent surfaces, semi-transparent surfaces, glass, building exteriors, building interiors, roofs, metal surfaces, vehicle (electric, gas, or hybrids thereof) surfaces, portable consumer products (e.g., calculators, computers, cellular telephones, and the like), batteries, energy storage devices (e.g., secondary batteries, supercapacitors, and the like), and the like. In some embodiments, attachment to a surface and/or cell frame may be via a mounting device. In some embodiments, said mounting devices may be operable to manipulate said photovoltaic device, e.g., to maximize direct exposure to the sun.

In some embodiments, photovoltaic modules or components thereof may include a plurality of photovoltaic devices such that at least one photovoltaic device comprises at least one backsheet of the present invention and a photovoltaic material. In some embodiments, photovoltaic modules or components thereof may comprise a module frame for holding the plurality of photovoltaic devices in a set relational configuration, where at least one photovoltaic device includes at least one backsheet of the present invention. In some embodiments, module frames may include or be operably connected to mounting devices. In some embodiments, said mounting devices may be operable to manipulate said photovoltaic module, e.g., to maximize direct exposure to the sun. Some embodiments may involve attachment of photovoltaic modules or components thereof to a surface. Some embodiments may involve attachment of photovoltaic devices or components thereof to a module frame.

In some embodiments, mounting devices may be on the photovoltaic devices or photovoltaic modules including frames thereof, on at least a portion of the photovoltaic devices or photovoltaic modules including frames thereof, integrated into photovoltaic devices or photovoltaic modules including frames thereof, and/or separate yet capable of operable connection to the photovoltaic devices or photovoltaic modules including frames thereof. Suitable mounting devices may include, but are not limited to, rails, fasteners, interconnecting male and female parts, tongue and groove elements, c-clamps, magnets, adhesives, screws, nails, frames, fabric hook-and-loop fasteners, electrically conductive connectors, buttons, or any combination thereof. Further, said mounting devices may include locking mechanisms.

In some embodiments, photovoltaic modules and the like or components and frames thereof may comprise mounting devices for receiving at least a portion of a photovoltaic device or frame thereof (or plurality thereof) in a set relational configuration, such that the photovoltaic device (or at least one of) includes at least one backsheet of the present invention. In some embodiments, said mounting devices may be operable to manipulate said photovoltaic device or frame thereof, e.g., to maximize direct exposure to the sun.

In some embodiments, a kit may include at least one photovoltaic device or component thereof comprising at least one backsheet of the present invention and a set of instructions (e.g., instructions for installation, replacement, maintenance, and/or removal of photovoltaic devices or components thereof). In some embodiments, the kit may further comprise at least one mounting device capable of holding the photovoltaic device in a set position. In some embodiments, the kit may further comprise at least one mounting device for attachment of the photovoltaic devices or components thereof to a surface, device frame, and/or module frame. In some embodiments, said surfaces may include, but are not limited to, windows, transparent surfaces, semi-transparent surfaces, glass, building exteriors, building interiors, roofs, metal surfaces, vehicle (electric, gas, or hybrids thereof) surfaces, portable consumer products (e.g., calculators, computers, cellular telephones, and the like), batteries, energy storage devices (e.g., secondary batteries, supercapacitors, and the like), and the like.

In some embodiments, a photovoltaic array may comprise a photovoltaic devices and/or photovoltaic modules that comprise at least one backsheet of the present invention and a set of instructions.

In some embodiments, a kit may include at least one photovoltaic module or component thereof comprising at least one photovoltaic device or component thereof that comprises at least one backsheet of the present invention and a set of instructions (e.g., instructions for installation, replacement, maintenance, and/or removal of photovoltaic modules or components thereof). In some embodiments, the kit may further comprise at least one mounting device for integration of the photovoltaic modules or components thereof into a photovoltaic array. In some embodiments, the kit may further comprise a module frame that enables for integration of the photovoltaic modules into a photovoltaic array.

Some embodiments may involve installing, replacing, and/or removing photovoltaic devices or components thereof (in a device frame or otherwise) relative to a module frame, such that the photovoltaic device (or at least one of) includes at least one backsheet of the present invention. Some embodiments may involve installing, replacing, and/or removing photovoltaic modules or components thereof (in a module frame or otherwise) relative to a photovoltaic array, such that the photovoltaic module (or at least one photovoltaic device thereof) includes at least one backsheet of the present invention. In some embodiments, photovoltaic modules or frame thereof may be capable of integrating the photovoltaic module into a photovoltaic array, such that the photovoltaic module (or at least one photovoltaic device thereof) includes at least one backsheet of the present invention.

Generally, layered articles according to any embodiments disclosed herein including kits thereof according to any embodiments disclosed herein, components thereof according to any embodiments disclosed herein, and methods of relating thereto according to any embodiments disclosed herein may comprise at least one backsheet of the present invention according to any embodiments disclosed herein, e.g., backsheets of the present invention having any one or more of the following features in any combination: a single layer structure, a multi-layer structure, a desired molecular weight distribution of the high to ultrahigh molecular weight polyethylene according to any embodiment disclosed herein, a desired thickness of the backsheet according to any embodiment disclosed herein, the desired properties of the backsheet according to any embodiment disclosed herein (e.g., relative thermal index, peel strength to an ethylene vinyl acetate copolymer encapsulant film, partial discharge value, dielectric strength, or any combination thereof), and/or the desired additives of the backsheets according to any embodiment disclosed herein. Further, said layered articles including kits thereof, components thereof, and methods of relating thereto may further comprise additional layers in any combination as described herein, e.g., substantially transparent solids, other encapsulant films, photovoltaic materials, adhesives, anti-reflective films, electrodes, polymeric films, substantially transparent resin films, and the like, or any combination thereof.

Generally, photovoltaic devices according to any embodiments disclosed herein, photovoltaic modules according to any embodiments disclosed herein, and photovoltaic arrays according to any embodiments disclosed herein including kits thereof according to any embodiments disclosed herein, components thereof according to any embodiments disclosed herein, and methods of relating thereto according to any embodiments disclosed herein may comprise in any combination at least one photovoltaic material and at least one backsheet of the present invention according to any embodiments disclosed herein, e.g., backsheets of the present invention having any one or more of the following features in any combination: a single layer structure, a multi-layer structure, a desired molecular weight distribution of the high to ultrahigh molecular weight polyethylene according to any embodiment disclosed herein, a desired thickness of the backsheet according to any embodiment disclosed herein, the desired properties of the backsheet according to any embodiment disclosed herein (e.g., relative thermal index, peel strength to an ethylene vinyl acetate copolymer encapsulant film, partial discharge value, dielectric strength, or any combination thereof), and/or the desired additives of the backsheets according to any embodiment disclosed herein. Further, said photovoltaic devices, photovoltaic modules, and photovoltaic arrays including kits thereof, components thereof, and methods of relating thereto may further comprise additional layers in any combination as described herein, e.g., substantially transparent solids, other encapsulant films, adhesives, anti-reflective films, electrodes, polymeric films, substantially transparent resin films, and the like, or any combination thereof.

To facilitate a better understanding of the present invention, the following examples of preferred embodiments are given. In no way should the following examples be read to limit, or to define, the scope of the invention.

### EXAMPLES

### Example 1

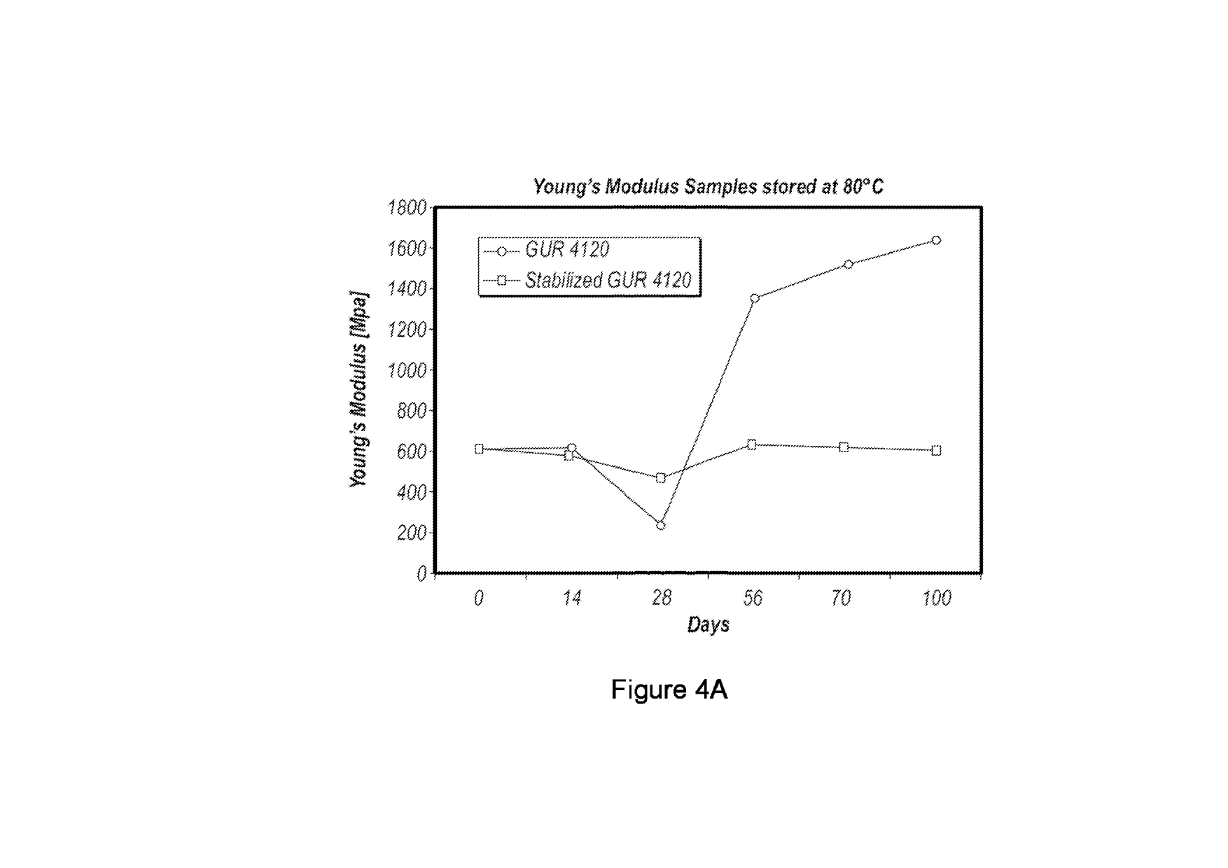

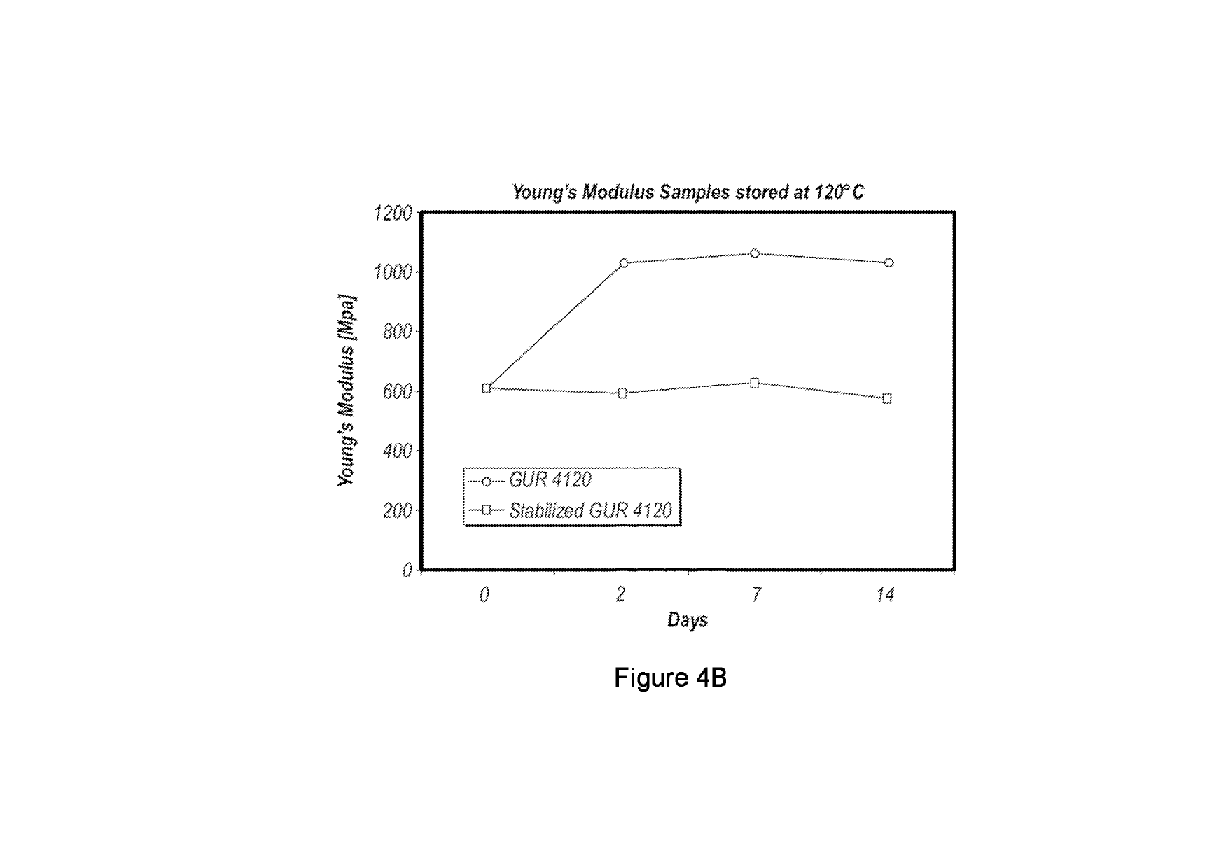

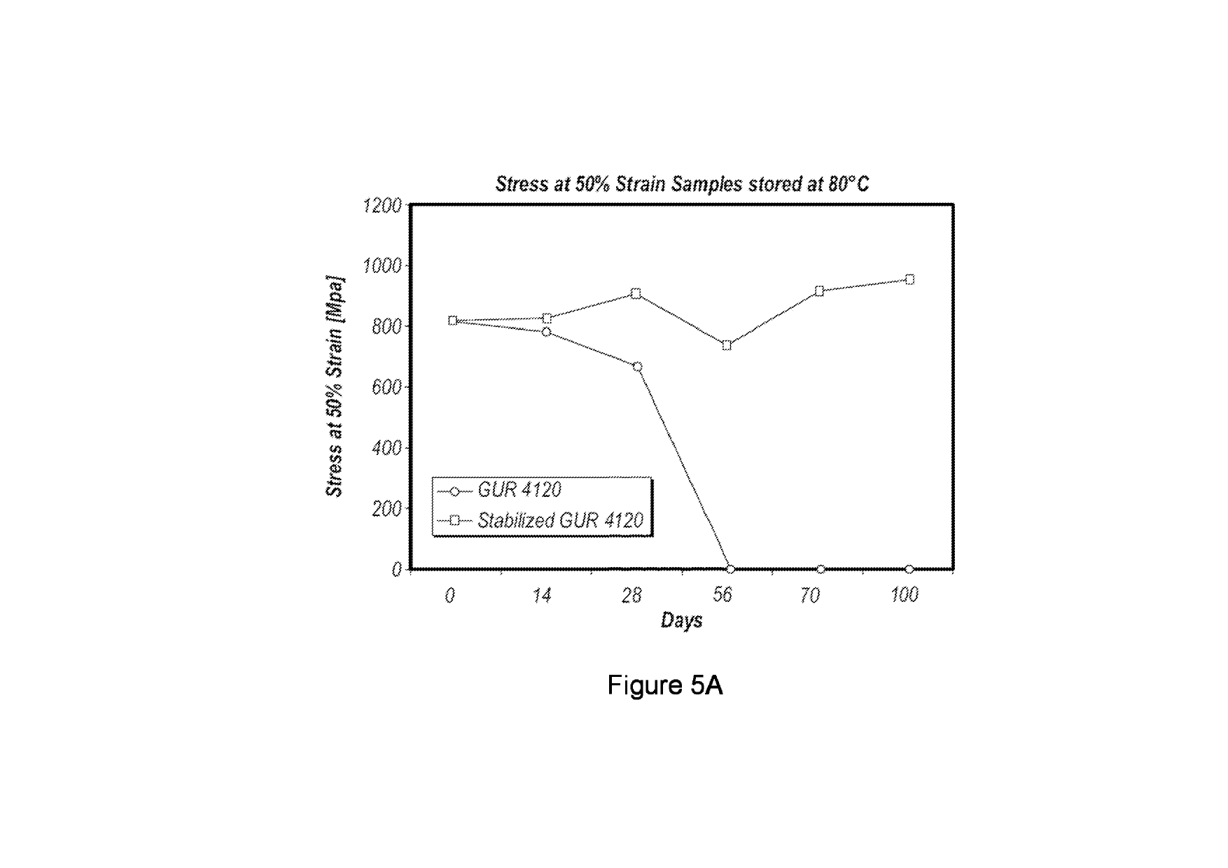

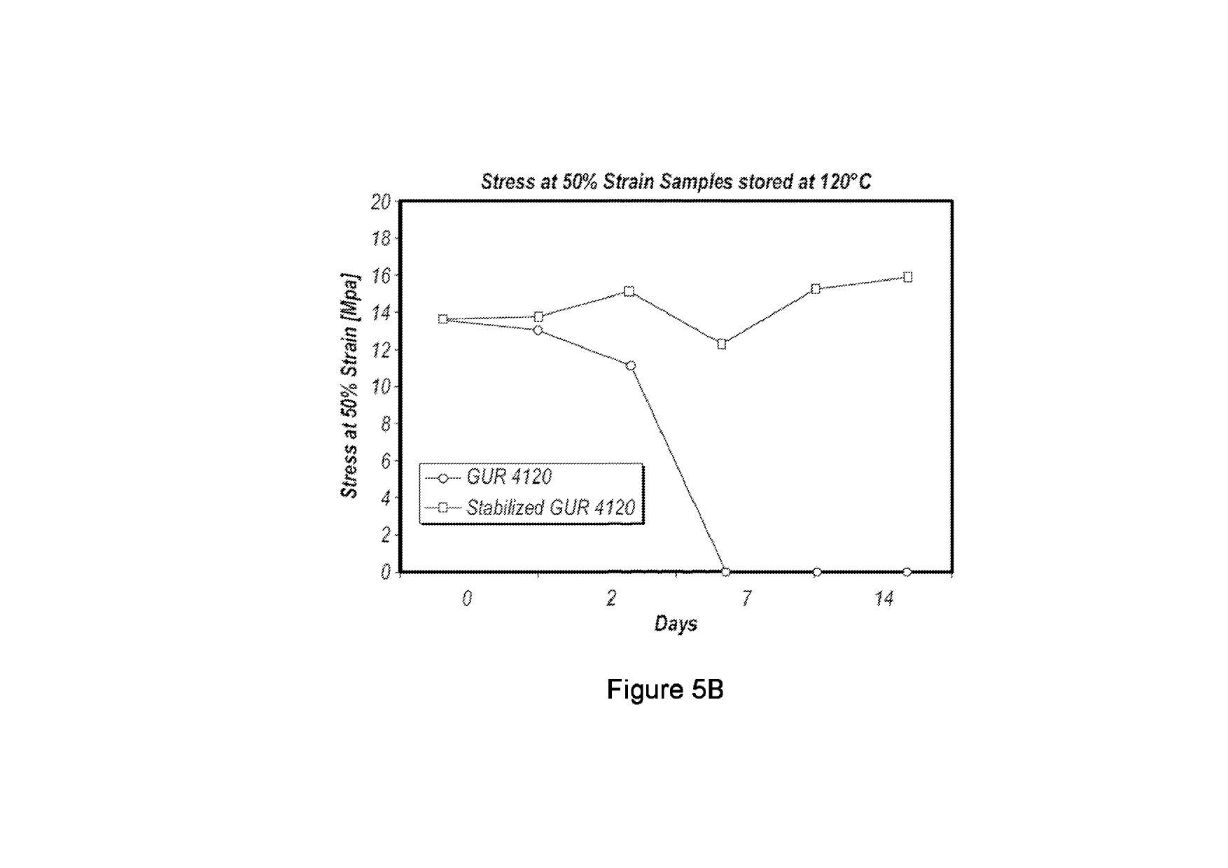

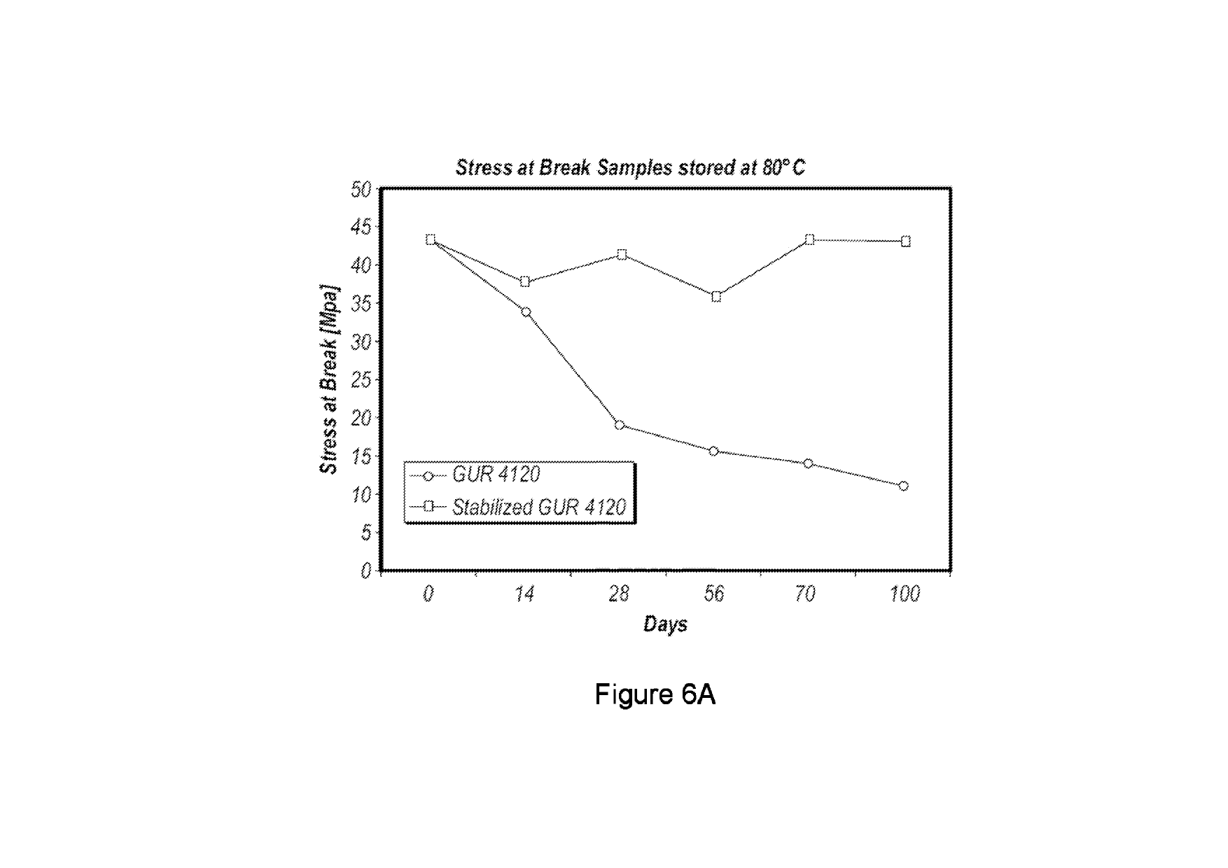

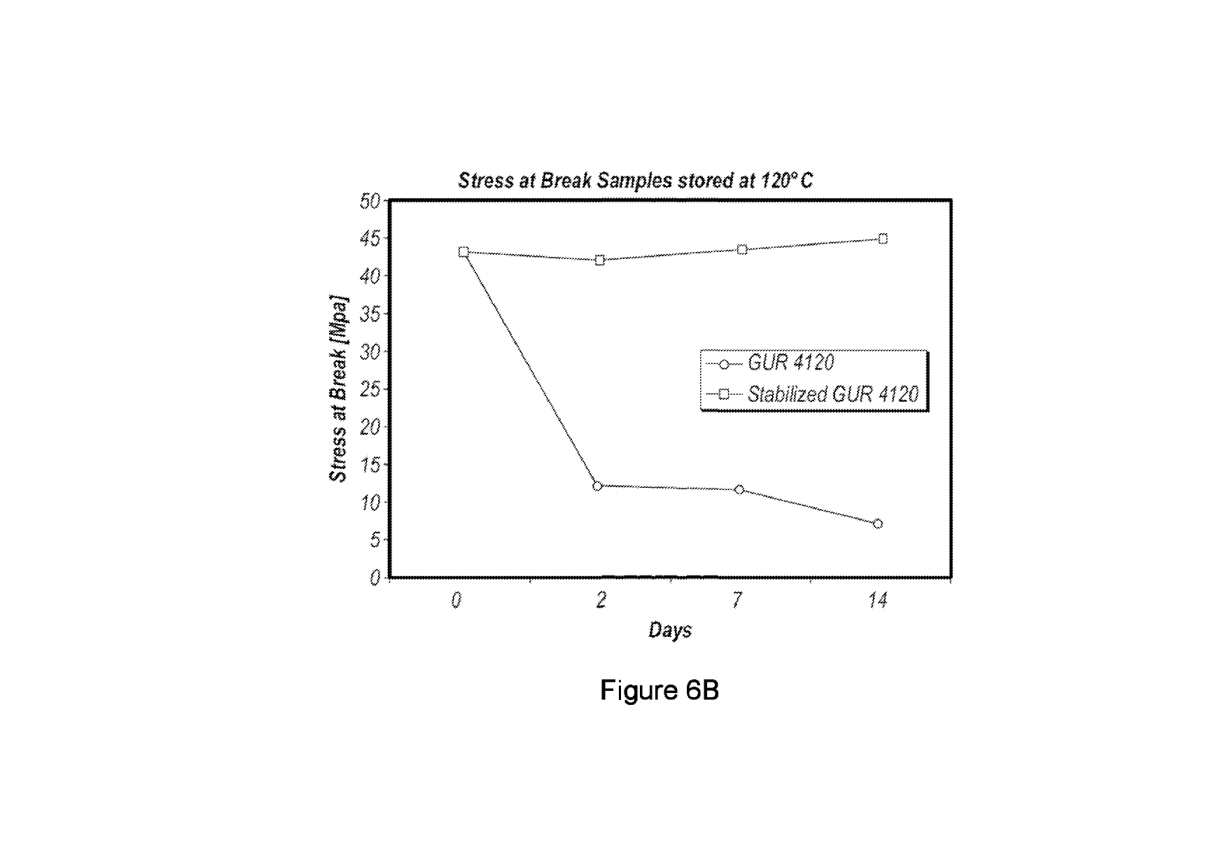

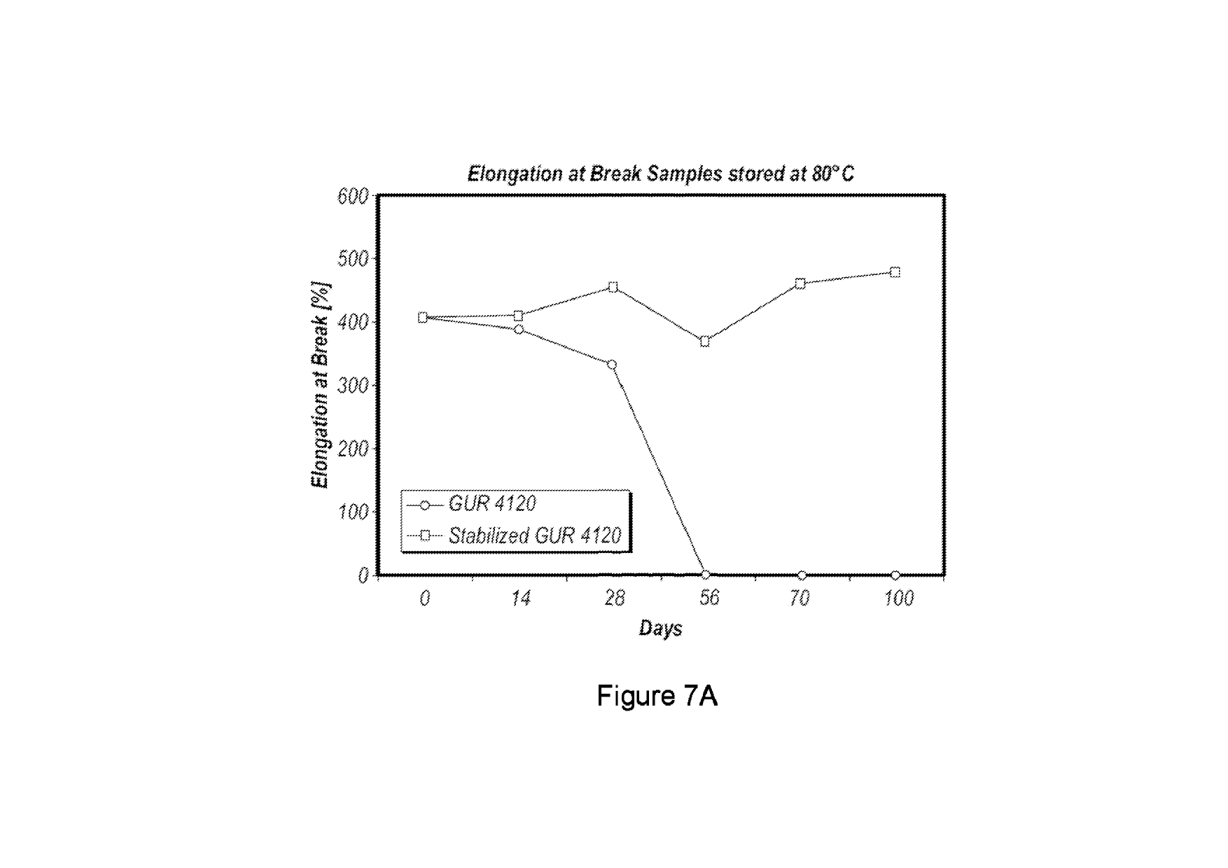

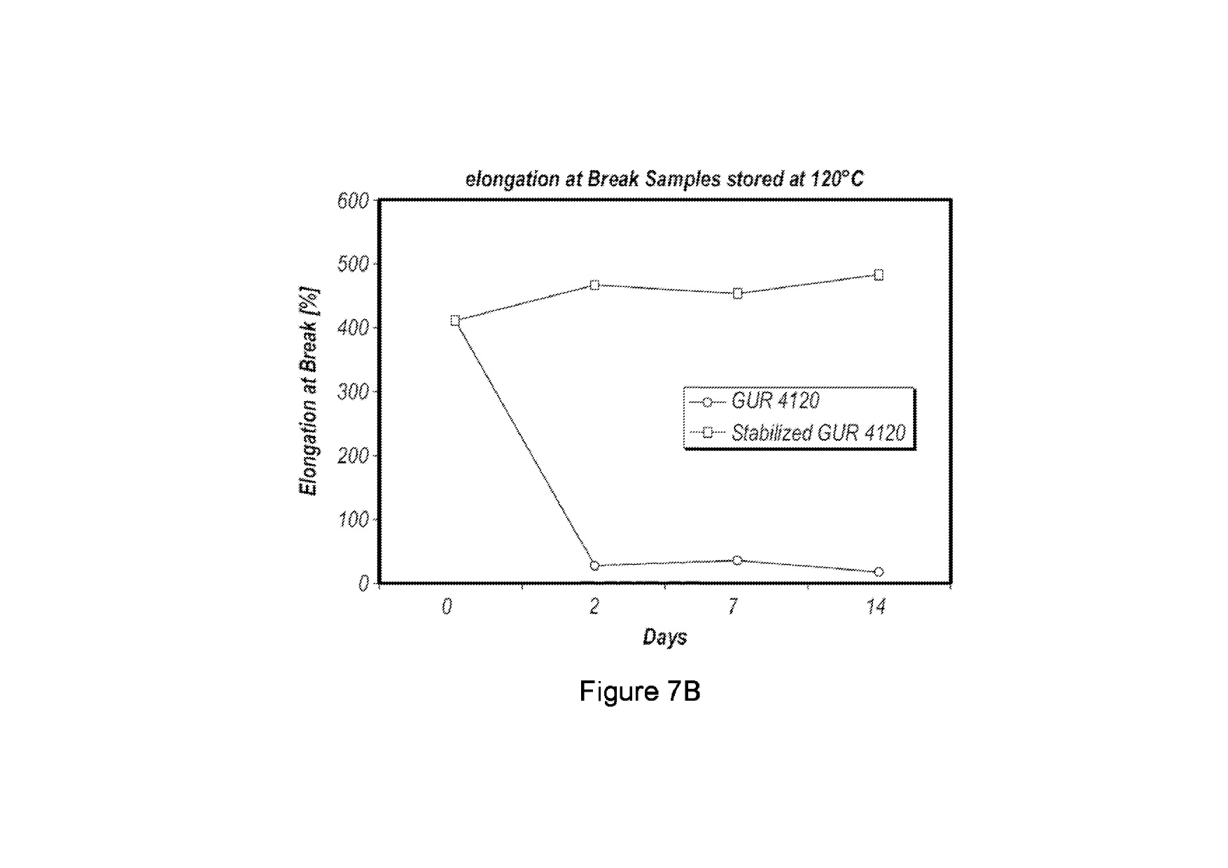

Long-Term Mechanical Stability at Increased Temperatures. Sample sheets with a thicknesses of 4 mm of GUR 4120 and GUR 4120 with a heat stabilizer (“stabilized GUR 4120”) were produced by compression molding. It should be noted that a 4 mm sample was used in this example so as to comply with the ISO standards of testing. GUR 4120 is polyethylene with an average molecular weight of 5,000,000 g/mol. The heat stabilizer used was a combination of a phenolic antioxidant and a phosphite antioxidant. The sample sheets were stored at elevated temperatures then tested for mechanical strength. A first set of samples were tested after exposure to 80° C. for 14 days, 28 days, 56 days, 74 days, and 100 days. A second set of samples were tested after exposure to 120° C. for 2 days, 7 days, and 14 days. The mechanical strength of the samples are provided in FIGS. 4-7. FIGS. 4A-B provide the Young's modulus data for the first and second set of samples, respectively. FIGS. 5A-B provide the stress at 50% strain data for the first and second set of samples, respectively. FIGS. 6A-B provide the stress at break data for the first and second set of samples, respectively. FIGS. 7A-B provide the elongation to break data for the first and second set of samples, respectively.

The GUR 4120 demonstrates an increase in Young's modulus and decrease in stress and strain relative to the stabilized GUR 4120. This example demonstrates that heat stabilizers can be added to high to ultrahigh density molecular weight polyethylene to achieve mechanical stability for prolonged time at reasonable operating temperatures of backsheets in photovoltaic devices.

Therefore, the present invention is well adapted to attain the ends and advantages mentioned as well as those that are inherent therein. The particular embodiments disclosed above are illustrative only, as the present invention may be modified and practiced in different but equivalent manners apparent to those skilled in the art having the benefit of the teachings herein. Furthermore, no limitations are intended to the details of construction or design herein shown, other than as described in the claims below. It is therefore evident that the particular illustrative embodiments disclosed above may be altered, combined, or modified and all such variations are considered within the scope and spirit of the present invention. The invention illustratively disclosed herein suitably may be practiced in the absence of any element that is not specifically disclosed herein and/or any optional element disclosed herein. While compositions and methods are described in terms of “comprising,” “containing,” or “including” various components or steps, the compositions and methods can also “consist essentially of” or “consist of” the various components and steps. All numbers and ranges disclosed above may vary by some amount. Whenever a numerical range with a lower limit and an upper limit is disclosed, any number and any included range falling within the range is specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values. Also, the terms in the claims have their plain, ordinary meaning unless otherwise explicitly and clearly defined by the patentee. Moreover, the indefinite articles “a” or “an,” as used in the claims, are defined herein to mean one or more than one of the element that it introduces. If there is any conflict in the usages of a word or term in this specification and one or more patent or other documents that may be incorporated herein by reference, the definitions that are consistent with this specification should be adopted.

The invention claimed is:

1. A solar cell backsheet comprising:
high to ultrahigh molecular weight polyethylene.

2. The solar cell backsheet of claim 1, wherein the solar cell backsheet is a single layer.

3. The solar cell backsheet of claim 1, wherein the solar cell backsheet has a water vapor transmission rate of about 20 g/m²*day or less.

4. The solar cell backsheet of claim 1, wherein the solar cell backsheet has a relative thermal index of about 90° C. to about 150° C.

5. The solar cell backsheet of claim 1, wherein the solar cell backsheet has a peel strength to an ethylene vinyl acetate copolymer encapsulant film of about 60 N/cm or greater.

6. The solar cell backsheet of claim 1, wherein the solar cell backsheet has a partial discharge value of about 1000 V or greater.

7. The solar cell backsheet of claim 1, wherein the solar cell backsheet has a dielectric strength of about 2500 V/mil or greater.

8. The solar cell backsheet of claim 1, wherein the high to ultrahigh molecular weight polyethylene has an average molecular weight from about 300,000 g/mol to about 20,000,000 g/mol.

9. The solar cell backsheet of claim 1, wherein the high to ultrahigh molecular weight polyethylene has an average molecular weight from about 5,000,000 g/mol to about 12,000,000 g/mol.

10. The solar cell backsheet of claim 1 further comprising:
at least one additive comprising at least one selected from the group consisting of: a heat stabilizer, an antioxidant, a light stabilizing additive, a UV absorber, a light diffusing agent, a halogenated flame retardant, a non-halogenated flame retardant, a reinforcing additive, a crosslinking agent, a lubricant, an optical brightener, a colorant, a metal deactivating agent, and any combination thereof.

11. The solar cell backsheet of claim 1, wherein at least a portion of the surface of the backsheet is a hydrophilic surface.

12. The solar cell backsheet of claim 1, wherein at least a portion of the surface of the backsheet is a hydrophobic surface.

13. The solar cell backsheet of claim 1, wherein the backsheet has a thickness of about 3 mm or less.

14. The solar cell backsheet of claim 1, wherein the backsheet has a thickness of about 10 microns to about 500 microns.

15. A method comprising:
providing a matrix material that comprises high to ultrahigh molecular weight polyethylene;
compression molding the matrix material into a billet; and
skiving the billet to yield a sheet having a thickness of about 3 mm or less.

16. The method of claim 15, wherein the sheet has a water vapor transmission rate of about 20 g/m²*day or less.

17. The method of claim 15, wherein the sheet has a relative thermal index of about 90° C. to about 150° C.

18. The method of claim 15, wherein the sheet has a peel strength to an ethylene vinyl acetate copolymer encapsulant film of about 60 N/cm or greater.

19. The method of claim 15, wherein the sheet has a partial discharge value of about 1000 V or greater.

20. The method of claim 15, wherein the sheet has a dielectric strength of about 2500 V/mil or greater.

21. A method comprising:
providing a matrix material that comprises high to ultrahigh molecular weight polyethylene; and
compression molding the matrix material into a sheet having a thickness of about 3 mm or less.

22. A photovoltaic device comprising:
a photovoltaic layer; and
a backsheet that comprises high to ultrahigh molecular weight polyethylene.

23. The photovoltaic device of claim 22, wherein the photovoltaic device is flexible.

24. The photovoltaic device of claim 22, wherein the photovoltaic layer comprises an organic photovoltaic material.

25. The photovoltaic device of claim 22, wherein the backsheet is a single layer.
